(19) United States
(12) Patent Application Publication
(10) Pub. No.: US 2026/0225290 A1
(43) Pub. Date: Aug. 6, 2026

(54) VEHICLE INTEGRATED SOLAR PANEL STRUCTURE, METHOD FOR MANUFACTURING SAME, AND VEHICLE INCLUDING SAME

(71) Applicants: HYUNDAI MOTOR COMPANY, SEOUL (KR); KIA CORPORATION, SEOUL (KR)

(72) Inventors: Yeonghee Lee, Hwaseong-si (KR); Taeho Jeong, Hwaseong-si (KR)

(73) Assignees: HYUNDAI MOTOR COMPANY, SEOUL (KR); KIA CORPORATION, SEOUL (KR)

(21) Appl. No.: 19/256,973

(22) Filed: Jul. 1, 2025

(30) Foreign Application Priority Data
Feb. 4, 2025 (KR) 10-2025-0013584

(51) Int. Cl. B29C 43/20; H02S 20/30; H10F 19/80

(52) U.S. Cl. CPC B29C 43/20; H02S 20/30; H10F 19/804

(57) ABSTRACT

A solar panel structure is manufactured by disposing an additional layer on an existing vehicle body outer panel and performing a laminating process on the additional layer without requiring an additional process such as preforming or mold fabrication. A method for manufacturing a solar panel structure includes disposing a vehicle body panel layer on a heating device, forming a thermal gap between the heating device and the vehicle body panel layer, disposing a solar module layer on the vehicle body panel layer, disposing a cover layer on the solar module layer, and pressing an upper portion of the cover layer.

### CROSS REFERENCE TO RELATED APPLICATIONS

This present application claims the benefit of priority to Korean Patent Application No. 10-2025-0013584, entitled “VEHICLE BODY-INTEGRATED SOLAR PANEL STRUCTURE, MANUFACTURING METHOD THEREOF, AND AUTOMOBILE COMPRISING THE SAME,” filed on February 4, 2025, in the Korean Intellectual Property Office, the entire disclosure of which is incorporated herein by reference.

### FIELD

The present disclosure relates to a solar panel structure that is manufactured by disposing an additional layer on an existing vehicle body outer panel and performing a lamination process without requiring an additional process such as preforming or mold fabrication, a method for manufacturing the same, and a vehicle including the same.

### BACKGROUND

Vehicle-integrated solar panel technology enables power generation by applying solar cells to body panels of a vehicle, such as the doors, hood, and roof, regardless of whether the vehicle is stationary or in motion. Among these applications, the "solar roof" is a representative example, in which solar cells are integrated into a roof, where glass can be used. As a result, most existing solar panels have been developed using glass-based structures.

However, except when used in the roof, glass is generally not suitable for closure parts such as hoods, doors, and lids, due to safety concerns and complex shapes. Therefore, developing alternative materials to glass is preferred to facilitate the application of solar cells to these parts.

However, the use of such alternative materials in manufacturing vehicle-integrated solar panels poses challenges, as it leads to higher production costs and longer manufacturing times. Accordingly, ongoing research aims to improve time and cost efficiency while increasing productivity by streamlining the manufacturing process.

### SUMMARY

The present disclosure is directed to providing a solar panel structure by disposing additional layers on a vehicle body outer panel and performing a lamination process, as well as a method for manufacturing the same and a vehicle including the same.

An aspect of the present disclosure provides a solar panel structure including a vehicle body panel layer, a solar module layer disposed on the vehicle body panel layer, and a cover layer disposed on the solar module layer.

Another aspect of the present disclosure provides a vehicle including the solar panel structure according to one aspect of the present disclosure.

Still another aspect of the present disclosure provides a method for manufacturing a solar panel structure, the method including disposing a vehicle body panel layer on a heating device, forming a thermal gap between the heating device and the vehicle body panel layer, disposing a solar module layer on the vehicle body panel layer, disposing a cover layer on the solar module layer, and pressing an upper portion of the cover layer.

The method for manufacturing a solar panel structure according to the present disclosure does not include additional processes such as preforming or mold fabrication.

Therefore, the time required for manufacturing the solar panel structure can be reduced, and costs associated with additional processes can be eliminated, making the process more economical.

According to the method for manufacturing the solar panel structure according to the present disclosure, additional layers can be disposed on the vehicle body panel layer, specifically the vehicle body outer panel, followed by a lamination process. Therefore, productivity can be improved.

The solar panel structure according to the present disclosure may include ethylene-vinyl acetate copolymer (EVA) as an encapsulation layer.

Therefore, unlike the case where thickness variation occurs between the central portion and the edge portion when laminating a solar panel structure using existing composite materials such as fibers and resin, the solar panel structure of the present disclosure may have no thickness variation between the central portion and the edge portion.

According to the method for manufacturing the solar panel structure of the present disclosure, the solar module layer can be disposed on a curved surface without using additional adhesive or primer, allowing the solar panel structure to have a reduced thickness.

Therefore, the reduction in spacing and height variations with adjacent components can expand potential applications.

### BRIEF DESCRIPTION OF THE FIGURES

The foregoing and other aspects, features, and advantages, as well as the following detailed description of the embodiments, will be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIGS. 1, 2, and 3 schematically illustrate a method for manufacturing a solar panel structure according to an embodiment of the present disclosure.

FIG. 4 schematically illustrates a thermal gap filled with a thermally conductive filler according to an embodiment of the present disclosure.

FIG. 5 schematically illustrates a thermal gap 100 having the radiation film positioned therein according to an embodiment of the present disclosure.

FIG. 6 is a cross-sectional view illustrating a solar panel structure according to an embodiment of the present disclosure.

FIG. 7 schematically illustrates a solar panel structure together with a thermal gap according to an embodiment of the present disclosure.

### DETAILED DESCRIPTION

The terms used in the detailed description, including technical or scientific terms, have the same meaning as would be commonly understood by a person skilled in the art in the technical field of the present disclosure, unless specifically defined otherwise. It will be further understood that terms in common usage should also be interpreted as is customary in the relevant art and not in an idealized or overly formal sense unless expressly so defined herein.

Furthermore, these terms such as "first," "second," and other numerical terms, are used only to distinguish one element from another element. These terms are generally only used to distinguish one element from another. For example, without departing from the scope of the present disclosure, the first component may be referred to as the second component, and similarly, the second component may be referred to as the first component.

The terminology used herein is used for the purpose of describing particular exemplary embodiments only and is not intended to be limiting. A singular form may include a plural form if there is no clearly opposite meaning in the context. In the following description, the terms "include," "comprise," "have," and the like designate the existence of features, steps, elements, and combinations thereof, but should not be understood as precluding the existence or addition of one or more other features, steps, elements, and combinations thereof.

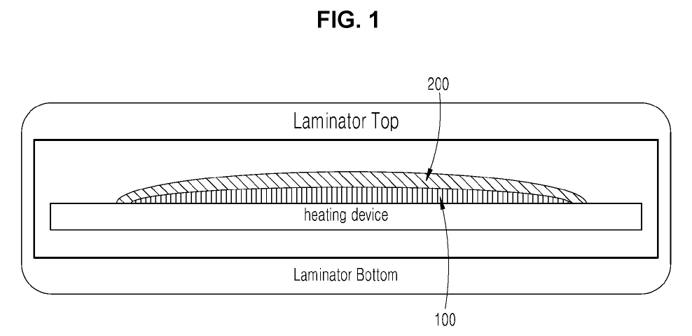

Hereinafter, embodiments of the present disclosure will be described in detail with reference to FIGS. 1 to 3.

FIGS. 1 to 3 schematically illustrate a method for manufacturing a solar panel structure according to an embodiment of the present disclosure. In FIGS. 1 to 3, the size, thickness, and shape of each component and device are merely exemplary and are not limited to the specific dimensions or shapes illustrated.

A method for manufacturing a solar panel structure of the present disclosure may include disposing a vehicle body panel layer 200 on a heating device, forming a thermal gap 100 between the heating device and the vehicle body panel layer 200, disposing a solar module layer 300 on the vehicle body panel layer 200, disposing a cover layer 400 on the solar module layer 300, and pressing an upper portion of the cover layer 400.

Referring to FIGS. 1 to 3, the solar panel structure of the present disclosure may be manufactured within a laminating device.

In the present disclosure, the laminating device is configured such that a vacuum device and a heating plate may be disposed at the bottom, and a plurality of layers may be stacked and pressed on the heating plate.

The term "laminating device" as used herein refers to a well-known structural component commonly utilized in industrial, laboratory, and commercial applications for stacking multiple layers of material and applying pressure to achieve lamination. Such devices include, but are not limited to, mechanical press laminators, roller-based laminators, vacuum laminators, thermal laminators, and other conventional lamination systems known in the art.

In the present disclosure, laminating or lamination refers to a process conducted within the laminating device.

FIG. 1 illustrates disposing a vehicle body panel layer 200 on a heating device within a laminating device and forming a thermal gap 100 between the heating device and the vehicle body panel layer 200.

The term "heating device" as used herein refers to a well-known structural component commonly employed in industrial, laboratory, and commercial applications to generate and transfer heat. Such devices include, but are not limited to, electric resistance heaters, induction heaters, infrared heaters, conduction-based heating plates, and other conventional heating elements known in the art.

A person skilled in the art would recognize that a heating device typically comprises a heat source, a temperature control mechanism, and a heat transfer surface or medium to deliver heat to a target. In various embodiments, the heating device may take the form of a flat plate heater, a tubular heater, a coil heater, or any other commercially available heating system capable of achieving the required temperature for the described process. The heating device may be implemented as an electric heating coil, a ceramic heating element, a metal plate heater, or a fluid-based heating system, where heat is generated and transferred via conduction, convection, or radiation.

In an embodiment of the present disclosure, the heating device may be in the form of a heating plate.

The heating device may be positioned below a solar panel structure and transfer heat to the solar panel structure within the laminating device.

The vehicle body panel layer 200 of the present disclosure may be a vehicle body outer panel, such as a vehicle door, hood, or roof, and include at least one or more of iron, aluminum and any combination thereof. However, it is not limited thereto, and any material that may maintain the required rigidity of the vehicle body outer panel while having high thermal conductivity may be used.

Meanwhile, the vehicle body panel layer 200 of the present disclosure may have a curvature. Therefore, the edge portion of the vehicle body panel layer 200 may be in contact with the heating device, while the central portion may have a convex shape, causing the central portion of the vehicle body panel layer 200 to be spaced apart from the heating device.

The thermal gap 100 of the present disclosure may refer to a space formed between the vehicle body panel layer 200 having the aforementioned shape and the heating device. The thermal gap 100 may be formed between the vehicle body panel layer 200 and the heating device and serve as a passage for transferring heat generated from the heating device to the vehicle body panel layer 200 and further to the solar panel structure.

Accordingly, the vehicle body panel layer 200 receiving heat from the heating device may reach a surface temperature of 100 °C to 150°C.

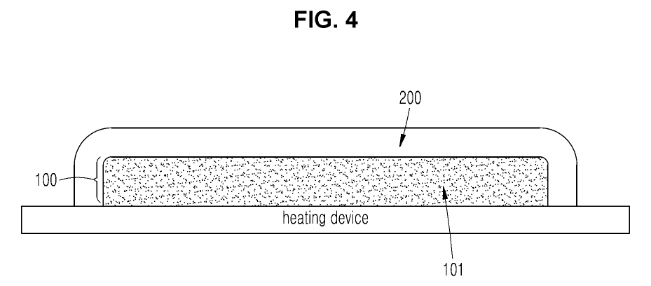

According to an embodiment of the present disclosure, the thermal gap 100 may be filled with a thermally conductive filler 101, as shown in FIG. 4. The thermally conductive filler 101 may include a liquid-type thermally conductive filler. In one example, the thermally conductive filler 101 may include at least one of thermally conductive grease, thermally conductive epoxy, or thermally conductive gel as a thermal interface material (TIM).

The thermally conductive grease may include at least one of carbon, aluminum oxide, boron nitride, or silica. The thermally conductive epoxy may include at least one of aluminum oxide, silver (Ag), or a mixture of ceramic and epoxy. The thermally conductive gel may include at least one of aluminum nitride, boron nitride, or a mixture of silica and polymer gel. However, it is not limited thereto, and any thermally conductive material that may fill the thermal gap 100 and then be cured may be used.

The thermally conductive filler 101 may be disposed in the space between the heating device and the vehicle body panel layer 200, that is, in the thermal gap 100, and then cured. FIG. 4 schematically illustrates a thermal gap 100 filled with a thermally conductive filler 101. The shapes of the heating device, the thermal gap 100, and the vehicle body panel layer 200 in FIG. 4 are merely exemplary and are not limited to the thickness or dimensions illustrated.

According to the present disclosure, the thermally conductive filler 101 fills the thermal gap 100 as shown in FIG. 4, thereby facilitating heat transfer to the solar panel structure within the laminating device. The heat transfer may occur through conduction.

According to an embodiment of the present disclosure, the thermal gap 100 of the present disclosure may have a radiation film 102 positioned therein. In one example, the radiation film 102 may include at least one of a silicone pad or a graphite sheet as a TIM.

The silicone pad may include at least one of aluminum nitride, boron nitride, or a mixture of ceramic and silicone. The graphite sheet may include at least one of pyrolytic graphite or natural graphite.

In another example, the radiation film 102 may include at least one of thermally conductive grease, thermally conductive epoxy, or thermally conductive gel as a TIM. The thermally conductive grease, thermally conductive epoxy, and thermally conductive gel may be the same as those described above and may be prepared by being cured into a thin film form.

According to an embodiment of the present disclosure, the radiation film 102 may have an emissivity of 0.9 or higher.

In an embodiment of the present disclosure, a plurality of the radiation films 102 may be provided. When the radiation films 102 are provided in a number of two, one radiation film 102 may be attached to an upper surface of the heating device, and the other radiation film 102 may be attached to a lower surface of the vehicle body panel layer 200.

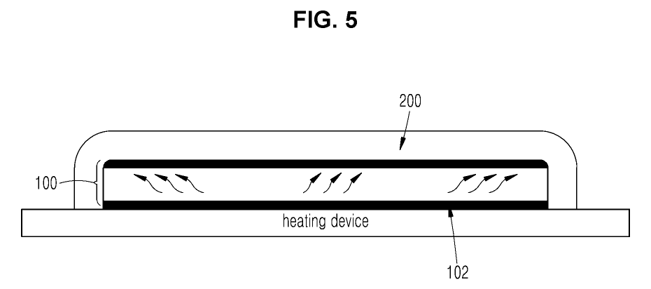

FIG. 5 schematically illustrates a thermal gap 100 having the radiation film 102 positioned therein. The shapes of the heating device, the thermal gap 100, the radiation film 102 and the vehicle body panel layer 200 in FIG. 5 are merely exemplary and are not limited to the thickness or dimensions illustrated.

The heat generated from the heating device may be transferred to the radiation film 102 attached to the upper surface of the heating device, and then transferred to the radiation film 102 attached to the lower surface of the vehicle body panel layer 200, as illustrated in FIG. 5. The heat transfer may occur through convection or radiation. The heat transfer is illustrated by arrows inside the thermal gap 100 in FIG. 5.

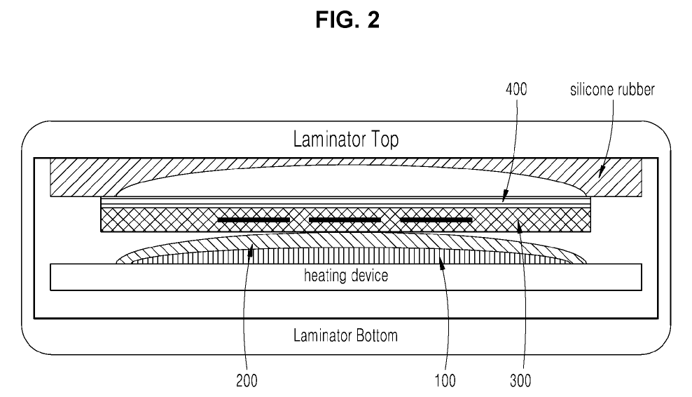

FIG. 2 illustrates disposing the solar module layer 300 on the vehicle body panel layer 200 and disposing the cover layer 400 on the solar module layer 300. Referring to FIG. 2, the laminating device of the present disclosure may include silicone rubber therein. The silicone rubber may be disposed on an upper portion of the laminating device to press an upper part of a structure during the final laminating process.

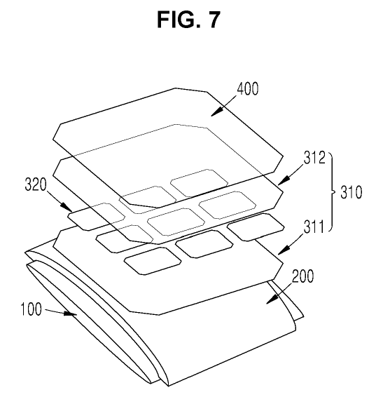

Referring to FIG. 7, the solar module layer 300 of the present disclosure may include an encapsulation layer 310 and a solar cell 320.

The encapsulation layer 310 may allow sunlight to pass through to the solar cell 320 and may protect the solar cell 320 from the external environment. A plurality of encapsulation layers 310 may be provided.

In the present disclosure, the encapsulation layer 310 may include a first encapsulation layer 311 and a second encapsulation layer 312. In one example, the first encapsulation layer 311 may be disposed below the solar cell 320, and the second encapsulation layer 312 may be disposed above the solar cell 320. That is, the first encapsulation layer 311 may be disposed between the solar cell 320 and the vehicle body panel layer 200. The second encapsulation layer 312 may be disposed between the solar cell 320 and the cover layer 400.

According to an embodiment of the present disclosure, the encapsulation layer 310 may include at least one or more of ethylene-vinyl acetate (EVA), polyolefin elastomer (POE), polyvinyl butyral (PVB) and any combination thereof.

In one example, the encapsulation layer 310 may include ethylene-vinyl acetate copolymer (EVA). EVA is a polymer material formed by the polymerization of ethylene and vinyl acetate and may have high thermal durability and improved transparency. EVA may also have improved adhesion to the solar cell. However, in the process of manufacturing a solar panel, insufficient heat control or repeated heating may lead to bubble formation. The present disclosure provides a single heating process that does not require repeated heating, and even when EVA is included in the encapsulation layer 310, bubble formation may be prevented. This will be described in detail below in conjunction with an explanation of the thickness variation of the solar panel structure.

The solar cell 320 of the present disclosure is a device configured to generate electricity using solar energy, and is not limited to a particular type. In the present disclosure, a plurality of solar cells 320 may be provided.

The cover layer 400 of the present disclosure may form the outermost layer of the solar panel structure and may include at least one or more of polycarbonate (PC), ethylene tetrafluoroethylene (ETFE), polymethyl methacrylate (PMMA) and any combination thereof. However, the present disclosure is not limited thereto, and any material that may maintain high transmittance to sunlight even after pressing the upper portion of the cover layer 400 may be used.

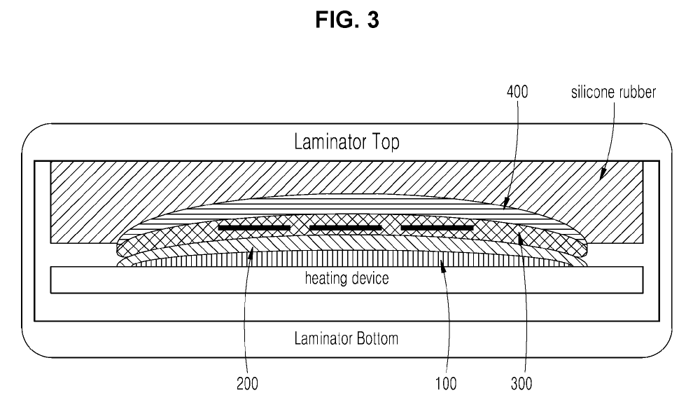

FIG. 3 illustrates pressing the upper portion of the cover layer 400. Referring to FIG. 3, during pressing the upper portion of the cover layer 400, the cover layer 400, the solar module layer 300, and the vehicle body panel layer 200 may be compressed, that is, laminated, by the silicone rubber. In this process, each layer may be pressed to conform to the shape of the vehicle body panel layer 200, which is curved. Accordingly, the cover layer 400 may be pressed to conform to the shape of the vehicle body panel layer 200.

In one example, the pressing the upper portion of the cover layer 400 of the present disclosure may be performed for 15 to 30 minutes.

According to an embodiment of the present disclosure, the pressing the upper portion of the cover layer 400 may ultimately be performed at a temperature of 100 to 150°C due to the heat transferred from the heating device described above.

The method for manufacturing the solar panel structure of the present disclosure may further include unloading the vehicle body panel layer 200, the solar module layer 300, and the cover layer 400 from the laminating device after laminating by pressing the upper portion of the cover layer 400.

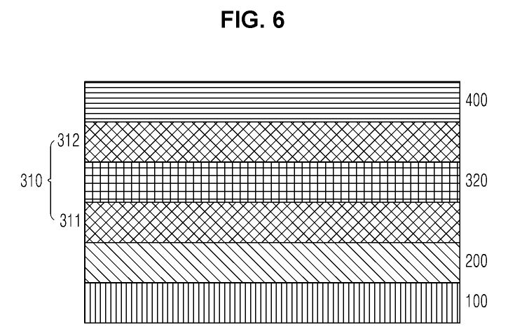

The solar panel structure of the present disclosure may be manufactured through the above processes. The solar panel structure of the present disclosure may include a vehicle body panel layer 200, a solar module layer 300 disposed on the vehicle body panel layer 200, and a cover layer 400 disposed on the solar module layer 300. FIGS. 6 and 7 schematically illustrate a solar panel structure according to an embodiment of the present disclosure.

FIG. 6 is a cross-sectional view illustrating a solar panel structure according to an embodiment of the present disclosure.

FIG. 7 schematically illustrates a solar panel structure together with a thermal gap 100 according to an embodiment of the present disclosure.

The shape of the solar panel structure shown in FIGS. 6 and 7 is merely exemplary and is not limited to the specific size or shape illustrated.

Unlike existing methods for manufacturing laminated structures or solar panel structures, the method for manufacturing the solar panel structure according to an embodiment of the present disclosure may have improved process productivity, a uniform surface, and a reduced thickness of the manufactured structure. The reasons for this are described below.

Widely used methods for manufacturing laminated structures may include the autoclave process, the resin transfer molding (RTM) process, and the long fiber injection (LFI) process.

All of the above processes may be based on composite materials. Composite materials may refer to reinforcements such as carbon fiber or glass fiber impregnated with a resin. The above processes may be performed by laminating multiple layers composed of reinforcements and a resin.

In the autoclave process, layers are stacked in a mold, followed by vacuum bagging to minimize bubbles or defects. The stacked structure is then disposed in an autoclave for batch pressurization and hot forming, resulting in a laminated structure.

In the RTM process, a laminated structure may be manufactured by disposing a reinforcing material (fiber) into a preform mold for shaping, then impregnating it with resin (and a curing agent) and performing hot forming.

In the LFI process, a preform may be manufactured by molding a face sheet including a material such as polymethyl methacrylate (PMMA) into a desired shape, then injecting a reinforcing material, such as fiber, into the preform to form a laminated structure.

As described above, existing processes may primarily utilize a preform or a mold in manufacturing laminated structures. For example, when laminating the solar module layer as in the present disclosure, the autoclave process requires the solar cell to be impregnated with resin, the RTM process requires the solar cell to be molded into a preform, and the LFI process requires the solar cell to be laminated with the face sheet. On the other hand, according to the present disclosure, since the solar module layer 300 and other components are directly disposed on the vehicle body panel layer 200 and then laminated by pressing, the manufacturing method may not require preforming or mold fabrication. Therefore, according to the present disclosure, the time and manufacturing cost required for producing a solar panel structure may be reduced, leading to a significant improvement in productivity.

Meanwhile, as described above, the encapsulation layer 310 according to an embodiment of the present disclosure may include EVA. EVA is a polymer material formed by polymerizing ethylene and vinyl acetate and may require a processing temperature of 130°C or higher. In existing processes, for example, in the LFI process, the reinforcement injection process is performed at around 90°C. Therefore, to laminate a solar module layer as in the present disclosure, EVA must be laminated on both the upper and lower surfaces of the solar cell before the subsequent lamination process. However, when a solar cell laminated with EVA, that is, a solar module layer, is laminated, EVA may undergo remelting or reheating, resulting in a degradation of material properties and reduced bonding strength with the face sheet or the LFI layer formed by fiber injection. As a result, issues such as delamination or bubble formation may occur between the solar module layer and other layers. To prevent such issues, an additional adhesive or primer may be applied between the solar module layer and the face sheet layer, or between the solar module layer and the LFI layer.

On the other hand, the method for manufacturing the solar panel structure according to the present disclosure may ensure a processing temperature of at least 130°C, which is required for EVA, enabling the lamination process to be performed without the need for additional bonding agents, using only the vehicle body panel layer 200, the solar module layer 300, and the cover layer 400. That is, the method according to the present disclosure eliminates the need for an additional adhesive or primer to dispose the solar module layer 300 on the vehicle body panel layer 200, allowing the structure to be formed with a reduced thickness.

In one example, the solar panel structure according to an embodiment of the present disclosure may have a thickness of 2.5 mm to 3.5 mm.

The solar panel structure of the present disclosure has a thickness that is approximately 60% of that of the laminated structure manufactured using the existing process, which reduces gap variation and height variation with adjacent components, thereby improving applicability.

Meanwhile, in the RTM process, one of the existing processes described above, the processing temperature required for EVA cannot be ensured, similar to the LFI process. As a result, when EVA is used as an encapsulant, the RTM process may require an additional heating step, leading to a multi-stage heating process. Consequently, EVA may undergo remelting or reheating, resulting in delamination or bubble formation between layers.

To address this issue, epoxy resin is used instead of EVA as an encapsulant in the RTM process to prevent delamination or bubble formation between layers.

However, as the process progresses, the fluidity of the resin and the resulting uneven heating may cause the epoxy resin to migrate from the central region to the edges, leading to thickness variation depending on the location.

On the other hand, as previously described, the solar panel structure according to the present disclosure is manufactured through a single heating process, in which the solar module layer 300 and the cover layer 400 are disposed on the vehicle body panel layer 200 and laminated, without multiple repeated heating. In this process, a processing temperature of 130°C, required for EVA, can be ensured, eliminating the need for reheating and preventing defects caused by reheating.

Therefore, even when EVA is used as an encapsulant in the solar panel structure according to the present disclosure, bubble formation during the lamination process may be prevented. As a result, the solar panel structure may have a uniform surface with no thickness variation between the central region and the edges.

The vehicle according to the present disclosure may include the solar panel structure according to any of the various embodiments described above. Therefore, the solar panel structure according to the present disclosure has a reduced thickness compared to existing vehicle solar panel structures, helping to prevent unnecessary increases in vehicle weight. Additionally, the advantages of the method for manufacturing the solar panel structure according to the present disclosure may reduce vehicle manufacturing time and lower process costs, resulting in improved productivity.

While the present disclosure has been described above in relation to its embodiments, it is to be understood that these are only examples and do not limit the present disclosure, and those skilled in the art in the field to which the present disclosure belongs will understand that various modifications and applications not described above are possible without departing from the essential characteristics of the present disclosure. Therefore, the spirit of the present disclosure should not be limited to the above-described embodiments, and it should be understood that not only the following claims, but also all ranges equivalent to or equivalently modified from these claims belong to the scope of the spirit of the present disclosure.

1. A solar panel structure, comprising:
a vehicle body panel layer;
a solar module layer positioned on the vehicle body panel layer; and
a cover layer positioned on the solar module layer.

2. The solar panel structure according to claim 1, wherein the solar module layer comprises an encapsulation layer and a solar cell.

3. The solar panel structure according to claim 2, wherein the encapsulation layer comprises at least one or more of ethylene-vinyl acetate copolymer (EVA), polyolefin elastomer (POE), polyvinyl butyral (PVB), and any combination thereof.

4. The solar panel structure according to claim 1, wherein the vehicle body panel layer comprises at least one or more of iron, aluminum, and any combination thereof.

5. The solar panel structure according to claim 1, wherein the cover layer comprises at least one or more of polycarbonate (PC), ethylene tetrafluoroethylene (ETFE), polymethyl methacrylate (PMMA), and any combination thereof.

6. The solar panel structure according to claim 1, wherein the solar panel structure has no thickness variation between a central portion and an edge portion.

7. The solar panel structure according to claim 1, wherein the solar panel structure has a thickness of 2.5 mm to 3.5 mm.

8. A vehicle comprising the solar panel structure according to claim 1.

9. A method for manufacturing a solar panel structure, the method comprising:
disposing a vehicle body panel layer on a heating device;
forming a thermal gap between the heating device and the vehicle body panel layer;
disposing a solar module layer on the vehicle body panel layer;
disposing a cover layer on the solar module layer; and
pressing an upper portion of the cover layer.

10. The method according to claim 9, wherein the vehicle body panel layer comprises at least one or more of iron, aluminum, and any combination thereof.

11. The method according to claim 9, wherein the thermal gap comprises a liquid-type thermally conductive filler.

12. The method according to claim 9, wherein the thermal gap comprises a radiation film.

13. The method according to claim 12, wherein the radiation film is attached to an upper portion of the heating device and a lower portion of the vehicle body panel layer.

14. The method according to claim 12, wherein the radiation film has an emissivity of 0.9 or higher.

15. The method according to claim 9, wherein the solar module layer comprises an encapsulation layer and a solar cell.

16. The method according to claim 15, wherein the encapsulation layer comprises at least one or more of ethylene-vinyl acetate copolymer (EVA), polyolefin elastomer (POE), polyvinyl butyral (PVB), and any combination thereof.

17. The method according to claim 9, wherein the cover layer comprises at least one or more of polycarbonate (PC), ethylene tetrafluoroethylene (ETFE), polymethyl methacrylate (PMMA), and any combination thereof.

18. The method according to claim 9, wherein the pressing the upper portion of the cover layer is performed for 15 to 30 minutes.

19. The method according to claim 9, wherein the pressing the upper portion of the cover layer is performed at a temperature of 100°C to 150°C.

20. The method according to claim 9, wherein the method does not use a preform or a mold.
